(19) United States
(12) Patent Application Publication
(10) Pub. No.: US 2010/0039117 A1
(43) Pub. Date: Feb. 18, 2010

(54) TEMPERATURE CONTROL SYSTEM FOR A DEVICE UNDER TEST

(75) Inventor: Robert JACOBS, Grass Valley, CA (US)

Correspondence Address: NIXON PEABODY, LLP, 401 9TH STREET, NW, SUITE 900, WASHINGTON, DC, 20004-2128, US

(73) Assignee: DCG SYSTEMS, INC., Fremont, CA (US)

(21) Appl. No.: 12/539,545

(22) Filed: Aug. 11, 2009

Related U.S. Application Data
(60) Provisional application No. 61/087,937, filed on Aug. 11, 2008.
(60) Provisional application No. 61/152,206, filed on Feb. 12, 2009.

(51) Int. Cl. G01R 31/02; F28F 7/00; F28F 27/00

(52) U.S. Cl. 324/537; 165/80.3; 165/80.4; 165/246; 165/247

(57) ABSTRACT

A temperature control system for an optical microscope for inspecting an integrated circuit device under test (DUT) that includes a first fluid circulation system coupled to and supplying fluid to fluid injectors that spray fluid on the DUT and a second fluid circulation system for exchanging energy between fluids in the first fluid circulation system and the second fluid circulation system (e.g., via a heat exchanger). The fluid injectors may be configured to mix the fluid and pressurized air that can be sprayed on the DUT to cool and/or heat the DUT.

### PRIORITY

The present application claims priority to U.S. Provisional Application No. 61/087,937, filed Aug. 11, 2008, and entitled “DUT TEMPERATURE CONTROL,” and U.S. Provisional Application No. 61/152,206, filed Feb. 12, 2009, the entireties of which are hereby incorporated by reference.

### BACKGROUND

1. Field

The subject invention relates to systems and methods for thermal management of an optical microscope for an integrated circuit device under test (DUT).

2. Related Art

Integrated circuits (ICs) are being used in increasing numbers of consumer devices, apart from the well-known personal computer itself. Examples include automobiles, communication devices, and smart homes (dishwashers, furnaces, refrigerators, etc.). This widespread adoption has also resulted in ever larger numbers of ICs being manufactured each year. With increased IC production comes the possibility of increased IC failure, as well as the need for fast and accurate chip probing, debug, and failure analysis technologies. The primary purpose of today's probing, debug, and failure analysis systems is to characterize the gate-level performance of the chip under evaluation, and to identify the location and cause of any actual or potential operational faults.

In the past, mechanical probes were used to quantify the electrical switching activity. Due to the extremely high circuit densities, speeds, and complexities of today's chips, including the use of flip-chip technology, it is now physically impossible to probe the chips mechanically without destructively disassembling them. Thus, it is now necessary to use non-invasive probing techniques for chip diagnostics. Such techniques involve, for example, laser-based approaches to measure the electric fields in silicon, or optically-based techniques that detect weak light pulses that are emitted from switching devices, e.g., field-effect transistors (FETs), during switching. Examples of typical microscopes for such investigations are described in, for example, U.S. Pat. Nos. 4,680,635; 4,811,090; 5,475,316; 5,940,545 and Analysis of Product Hot Electron Problems by Gated Emission Microscope, Khurana et al., IEEE/IRPS (1986), which are incorporated herein by reference.

During chip testing, the chip is typically exercised at relatively high speeds by a tester or other stimulating circuit. Such activity often results in considerable heat generation. When the device is encapsulated and is operated in its normal environment, various mechanisms are provided to assist in heat dissipation. For example, metallic fins are often attached to the IC, and cooling fans are provided to enhance air flow over the IC. However, when the device is under test, the device is not encapsulated and, typically, its substrate is thinned down for testing purposes. Consequently, no means for heat dissipation are available and the device under test (DUT) may operate under excessive heat so as to distort the tests, and may ultimately fail prematurely. Therefore, there is a need for effective thermal management of the DUT.

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, a temperature control system for an optical microscope for an integrated circuit device under test (DUT) is provided that includes a chamber; an optical receiver situated within the chamber; fluid injectors situated within the chamber; a first fluid circulation system coupled to and supplying fluid to the fluid injectors; and a second fluid circulation system for exchanging energy between fluids in the first fluid circulation system and the second fluid circulation system.

The optical receiver may include an objective lens.

The system may also include a solid immersion lens coupled to the objective lens.

The first fluid circulation system may not be in fluid communication with the second fluid circulation system.

The system may also include a heat exchanger coupled between the first fluid circulation system and the second fluid circulation system to exchange energy between the fluids in the first fluid circulation system and the second fluid circulation system.

The heat exchanger may include a thermal electric cooler.

The fluid injectors may include venturi injectors.

The venturi injectors may be structured to pass gas flow therein and mix liquid with the gas flow.

The venturi injectors may be connected to a pressurized gas source and a regulator that supply the gas flow to the venturi injectors.

The venturi injectors may also be connected to a gas heater that heats the gas flow supplied to the venturi injectors.

The first fluid circulation system may include a first reservoir situated within the chamber; and a second reservoir situated outside the chamber and coupled to the first reservoir. The system may also include a condenser coupled between the chamber and the second reservoir.

The second fluid circulation system may include a chiller.

The system may also include a seal structured to engage a DUT adapter plate and the chamber. The seal may be a vacuum assisted rubber seal.

The system may also include a controller coupled to the first fluid communication system and second fluid communication system to control the exchange of energy between the fluids in the first fluid communication system and the second fluid communication system.

The system may also include a pressure sensor and a temperature sensor to sense the pressure and temperature in the first fluid communication system and provide the pressure and temperature data to the controller, and a pressure sensor and a temperature sensor to sense the pressure and temperature in the second fluid communication and provide the pressure and temperature data to the controller.

According to another aspect of the invention, a temperature control system for an optical microscope for an integrated circuit device under test (DUT) is provided that includes a chamber; an optical receiver situated within the chamber; fluid injectors situated within the chamber; a fluid circulation system coupled to and supplying liquid and gas to the fluid injectors, the fluid injectors mixing the liquid and gas and spraying the mixture on the DUT; and a controller to control the supplying of the liquid and the gas to the fluid injectors.

The fluid injectors may be venturi injectors.

The system may also include a second fluid circulation system for exchanging energy between fluids in the fluid circulation system and the second fluid circulation system.

The fluid injectors may be connected to a pressurized gas source and a regulator that supply the gas to the fluid injectors.

The fluid injectors may also be connected to a gas heater that heats the gas supplied to the fluid injectors.

The fluid communication system may include a reservoir of liquid in the chamber, the reservoir connected to the fluid injectors to supply the liquid to the fluid injectors.

The fluid injectors may draw liquid from the reservoir of liquid when the gas is supplied to the fluid injectors.

The system may also include a pressure sensor and a temperature sensor to sense the pressure and temperature in the first fluid communication system and provide the pressure and temperature data to the controller.

The fluid circulation system may include a condenser that includes a plurality of condensing plates that are thermoelectrically coupled to a heat exchanger.

The fluid circulation system may include a reservoir, the reservoir fluidly coupled to the fluid injectors; a condenser comprising a plurality of condensing plates; a heat exchanger thermoelectrically coupled to the plurality of condensing plates, fluid supplied to the heat exchanger by circulated chilled water from a water chiller; thermoelectric coolers fluidly coupled to the reservoir and the heat exchanger; and a recirculation tank fluidly coupled to the reservoir and the condenser.

According to another aspect of the invention, a method for controlling the temperature of an integrated circuit device under test (DUT) in an optical microscope includes positioning the DUT in a chamber of the optical microscope; providing a first fluid circulation system for the cooling chamber; exchanging energy between fluids of the first fluid circulation system and a second fluid circulation system; and supplying fluid in the first fluid circulation system to a plurality of fluid injectors; and spraying the DUT with the fluid supplied to the plurality of fluid injectors.

Exchanging energy may include cooling the fluid of the first fluid circulation system.

Exchanging energy may include heating the fluid of the first fluid circulation system.

Supplying fluid to the plurality of fluid injectors may include supplying gas and liquid to the plurality of fluid injectors and mixing the gas and liquid in the fluid injectors, and spraying the DUT with the fluid using the plurality of fluid injectors may include spraying the DUT with the mixture.

According to a further aspect of the invention, a temperature control system for an optical microscope for an integrated circuit device under test (DUT) is described that includes a chamber; an optical receiver situated within the chamber; fluid injectors situated within the chamber; a reservoir coupled to the fluid injectors to supply fluid to the fluid injectors; an electronic regulator coupled to an air source to supply gas to the fluid injectors via a pump; and a controller coupled to the reservoir and the electronic regulator to monitor the temperature of the fluid in the reservoir and when the fluid reaches a predetermined temperature, sends a control signal to the electronic regulator to supply the gas to the fluid injectors and sends a control signal to the pump to supply the fluid to the fluid injectors.

The temperature control system may also include a condenser comprising a plurality of condenser plates; a heat exchanger coupled to a chiller; and a recirculation tank fluidly coupled to the condenser and the reservoir.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A is an exploded view of one embodiment of an optical inspection system according to one embodiment of the invention.

FIG. 1B is an exploded view of one embodiment of an optical inspection system according to one embodiment of the invention.

FIG. 1C is an exploded view of one embodiment of an optical inspection system according to one embodiment of the invention.

FIG. 2 is a schematic cross-sectional view of a temperature control system according to one embodiment of the invention.

FIG. 3 is a flow diagram of a cooling process according to one embodiment of the invention.

FIG. 4 is a flow diagram of a heating process according to one embodiment of the invention.

FIG. 5 is a schematic cross-sectional view of a temperature control system according to one embodiment of the invention.

FIG. 5A is a detailed view of the atomizer according to one embodiment of the invention.

FIG. 6 is a flow diagram of a cooling process according to one embodiment of the invention.

FIG. 7 is a flow diagram of a heating process according to one embodiment of the invention.

### DETAILED DESCRIPTION

A system for controlling the temperature of a semiconductor device under test (DUT) through the use of electronically temperature controlled fluids is described herein. A chamber is provided to control the temperature of the DUT while undergoing electrical testing with optical observation. The chamber houses the objective housing of the optical system and provides a fluid spray onto the DUT. The chamber has an independent fluid circulation system that exchanges energy with an external fluid circulation system through a heat exchanger. Venturi-based nozzles are provided in the chamber to spray the DUT which, in one embodiment, utilize air flow to draw liquid from an internal reservoir of the chamber's independent fluid circulation system and atomize that liquid as it exits the nozzle.

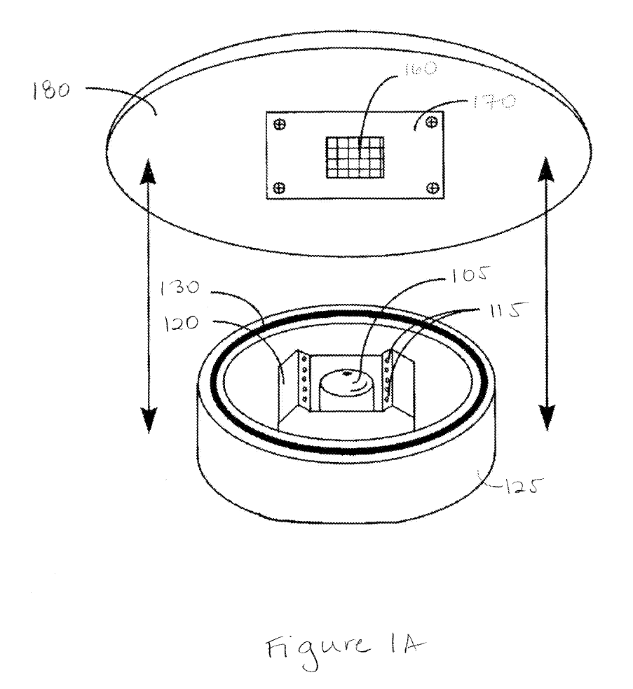

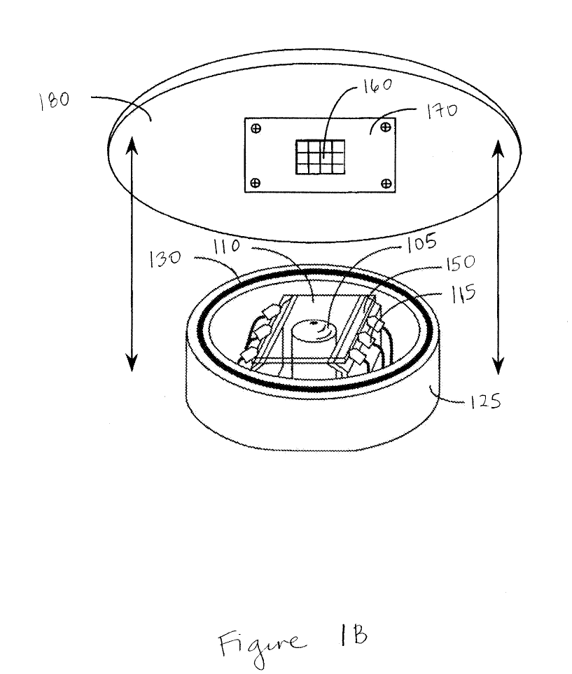

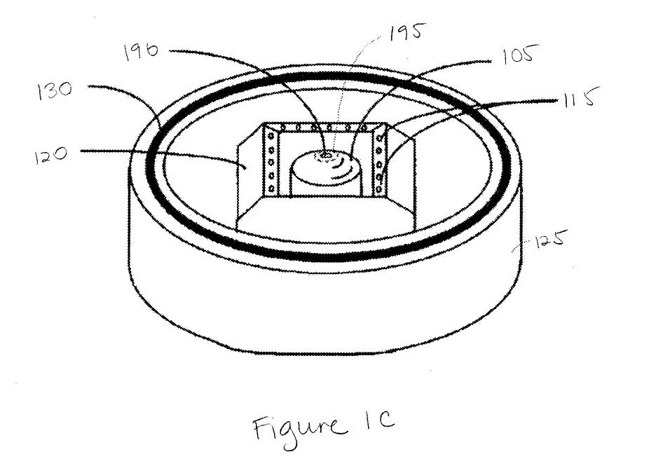

An embodiment of the invention will now be described in detail with reference to FIG. 1A. The system depicted in FIG. 1A may be used with any type of microscope used for inspection and/or testing of ICs. For clarity, FIG. 1A shows only the objective lens portion optical inspection/probing system. As shown in FIG. 1A, a retention frame 170 holds a DUT 160 onto a seal plate 180. The seal plate 180 is mounted to a load board, which in turn is connected to a conventional test head (not shown) of a conventional automated testing equipment (ATE). The ATE sends stimulating signals to the DUT 160, to simulate operating conditions of the DUT 160. This is done conventionally using the load board with an appropriate socket for the DUT 160.

An objective housing 105 houses the objective lens of the testing system. The objective housing 105 and objective lens generally form an optical receiver of the system, i.e., the probe head.

Spray jets or atomizers 115 are arranged so as to spray fluid onto the DUT 160. In FIG. 1A, the jets 115 are arranged on a spray head 120. The jets are shown here only schematically with respect to their size, number and arrangement. For example, while only two banks of atomizers are shown, four banks may be provided so as to cool the DUT 160. Also, in the context of this disclosure, the term “fluid” is used herein to signify both liquid and gaseous forms of the spray. Moreover, the jets 115 may be arranged circularly, rather than in a linear fashion. Similarly, the jets may be attached directly to any optical receiver used, e.g., objective lens housing, rather than placed in a spray head. Furthermore, various injectors or atomizers may be operated at different spray rates or be provided with different cooling fluid, or same cooling fluid, but at different temperature. Optionally, different spray heads may be adjusted to provide spray at different angles. In addition, although jets 115 are shown in FIG. 1A, it will be appreciated that other fluid injectors such as venturi tubes, orifice plates, valves, orifices, jets, nozzles and the like may be used to deliver fluid to the DUT 160.

The above assembly is situated inside a spray chamber 125, having a seal 130 affixed to its upper surface. The spray chamber 125 is affixed to a translation stage, e.g., an x-y-z stage (not shown). When performing testing in an embodiment employing the sliding seal, the spray chamber 125 is brought in contact with the sealing plate 180, so that the sliding seal 130 creates a seal with the sealing plate 180. The seal 130 may be hermetic, but a hermetic seal is not required, and the seal 130 may be made of porous material that prevents liquid splashing but enables air flow therethrough. In this manner, the spray chamber 125 may be moved about so as to bring the objective lens into registration with the particular area of the DUT 160 sought to be imaged, without breaking the seal with the sealing plate 180.

In another embodiment, the housing 125 is connected to the sealing plate 180 through a flexible bellows (not shown). The bellows material should be compatible with the fluid's temperature and chemical properties. Some potential materials include folded thin-walled steel and rubber.

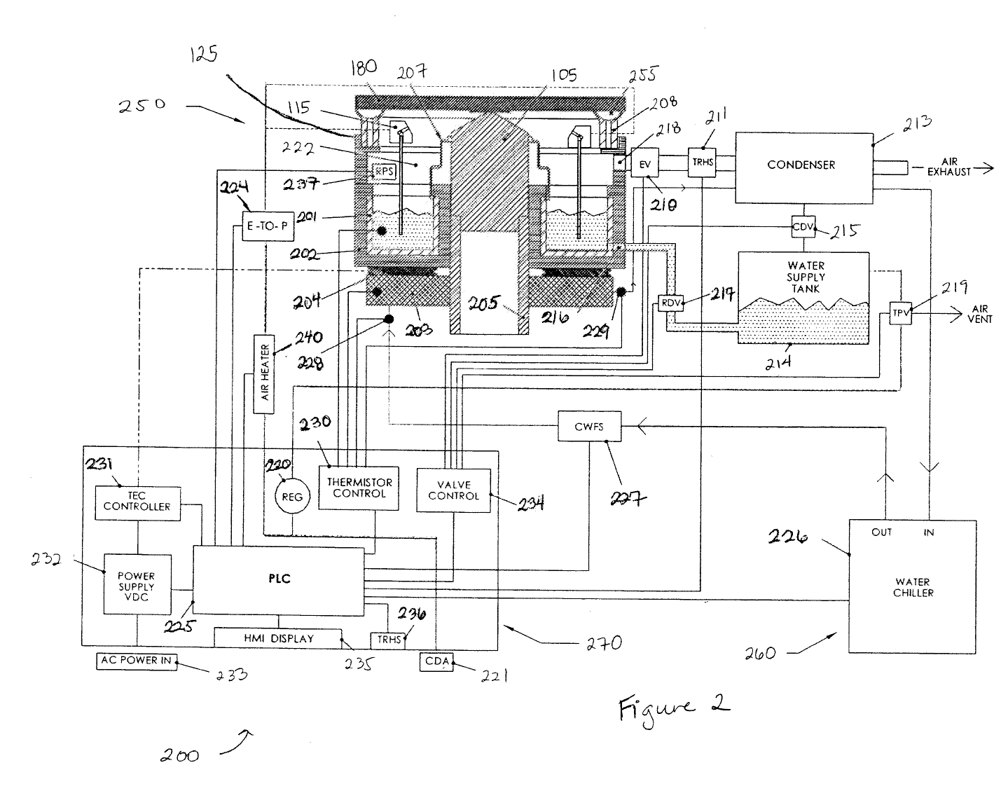

During testing, fluid is supplied to the jets/atomizers 115 via a temperature control system which is described in further detail with reference to FIGS. 2-4. Exemplary testing that occurs in the chamber 125 includes emission testing, such as static emission, dynamic emission, laser based testing, such as OBIRCH, TIVA, LIVA, CIVA, and the like.

FIG. 1B illustrates an alternative embodiment of the spray chamber 125 that additionally includes a transparent heat spreader 110 that is mounted onto a holder 150, which generally may be a metallic holder. As exemplified in FIG. 1B many of the elements of this embodiment are similar to those of the embodiments of FIG. 1A. The heat spreader 110 is made of a material that is permeable to the wavelength of radiation that is monitored by the particular tester used. For infrared, visible and UV radiation, the heat spreader may be made of ceramic, such as, for example, aluminum oxide, silicon oxide or mixture thereof. The heat spreader may also be made of a monocrystalline material such as, for example, sapphire. In one embodiment, the transparent heat spreader 110 is soldered, using, e.g., indium solder, to the holder 150. In the embodiment shown in FIG. 1B, the atomizers 115 are configured to spray fluid onto the periphery of the heat spreader 110.

It will be appreciated that in embodiments having the heat spreader 110, the objective housing 105 may alternatively be movable with respect to the heat spreader 110, so that once the heat spreader 110 is applied against the DUT 160 it need not be moved for testing different locations on the DUT 160.

In a further aspect of the invention, an improved imaging is obtained using a solid immersion lens (SIL) in combination with the objective lens. The SIL enables transmission of optical energy between the DUT and the objective lens practically regardless of the type and manner of cooling spray used. Thus, the atomizers and the fluid pressure can be selected for optimal heat removal efficiency.

FIG. 1C depicts an embodiment of the cooling system of the invention used in conjunction with a SIL. As exemplified in FIG. 1C many of the elements of this embodiment are similar to those of the embodiments of FIG. 1A. However, in this embodiment, a SIL 190 is affixed to the tip of the objective housing 105. In operation, the SIL 190 is “coupled” to the DUT 160, so as to allow communication of evanescent wave energy. In other words, the SIL 190 is coupled to the DUT 160 so that it captures rays propagating in the DUT 160 at angles higher than the critical angle (the critical angle is that at which total internal reflection occurs). As is known in the art, the coupling can be achieved by, for example, physical contact with the imaged object, very close placement (up to about 20-200 micrometers) from the object, or the use of index matching material or fluid. In addition to increasing the efficiency of light collection, the use of SIL 190 also prevents, or dramatically reduces, any deleterious effects of the mist on the image because the mist cannot intervene between the SIL 190 and the DUT 160. In one embodiment, the SIL 190 may, optionally, include an o-ring 195 or other protection device to protect the lens from the fluid.

FIG. 2 schematically illustrates one example of the temperature system 200. It will be appreciated that the system 200 described below is merely exemplary and may include a fewer or greater number of components, and that the arrangement of at least some of the components may vary from that described below and shown in FIG. 2.

The illustrated temperature system 200 includes the spray chamber 125 that includes an internal fluid circulation system 250, an external fluid circulation system 260 and a control system 270. The internal fluid circulation system 250 off loads its energy to the external fluid circulation system 260 via a heat exchanger 203. Energy is exchanged between the internal fluid circulation system 250 and the external fluid circulation system 260 without exchanging fluid between the internal and external fluid systems.

The control system 270 includes a Programmable Logic Circuit (PLC) 225 that is connected to the internal fluid communication system 250, the external fluid circulation system 260 and the heat exchanger 203. The control system 270 is configured to control the operation of the various components of the system 200 and monitor the temperature and pressure at various locations of the system 200.

The heat exchanger 203 may be any type of heat exchanger, such as, for example, shell and tube heat exchangers, plate heat exchangers, and the like. In one embodiment, the heat exchanger 203 is thermally connected to an optical extension sleeve 205 which in turn is connected to the microscope objective housing 105.

The external fluid circulation system 260 includes a chiller 226 that is connected to the heat exchanger 203 and a condenser 213. The chiller 226 provides chilled water to the heat exchanger 203 such that energy can be exchanged between the external fluid circulation system 260 and the internal fluid circulation system 250 at the heat exchanger 203. The condenser 213 is also connected to the heat exchanger 203 and supplies additional fluid to the chiller 226 to replace the fluid provided to the heat exchanger 203.

The internal fluid circulation system 250 is provided in the chamber 125. The internal fluid circulation system 250 includes a reservoir 201. The reservoir 201 is made with a material having high thermal conductivity such as copper or aluminum. The reservoir 201 is encased in an insulating jacket 202 that is made from a material having good insulating properties such as Kynar.

The reservoir 201 is connected to the heat exchanger 203 through thermal-electric coolers 204 via holes cut through the bottom of the insulating jacket 202.

A protective rubber boot 207 connects to the top of microscope objective 206 and is elastically sealed to reservoir 201. Optionally, a porous or solid seal 255 may be provided between the chamber 125 and a DUT adapter plate 180. In this example, a vacuum assisted rubber seal 208 creates a sealed chamber 222 between the insulating jacket 202 and the sealing plate 180.

An air exhaust port 218 in the insulating jacket 202 is connected to an exhaust valve 210 through a heat resistant flexible tube. The exhaust valve 210 is connected through a temperature-relative-humidity-sensor 211 to the condenser 213. The condenser 213 is connected to a water supply tank 214 through a condenser drain valve 215. The condenser 213 converts water vapor from the reservoir 201 back into liquid. This liquid is then supplied to the water supply tank 214.

A drain port 216 through the reservoir 201 and insulating jacket 202 is connected through a reservoir drain valve 217 to the water supply tank 214. The water supply tank 214 is also connected through a pneumatic line to tank pressure valve 219, a manual pressure regulator 220 and a pressurized air source 221. The tank pressure valve 219 provides pressurized air to the water supply tank 214 from the pressurized air source 221 that causes water in the water supply tank 214 to back-fill into the reservoir 201.

The atomizers 115 are located within the sealed chamber 222. In one embodiment, the atomizers 115 are air driven venturi atomizers and are connected to a regulator 224 that is electronically controlled by the PLC 225. The regulator 224 is connected pneumatically through the air heater 240 to the pressurized air source 221. The atomizers 115 are also fluidly connected to the reservoir 201 which supplies fluid to the atomizers. The pressurized air source 221 supplies the pressurized air to an entrance of the a venturi nozzle of the atomizers 115. When the pressurized air passes through the venturi nozzle, a vacuum is created that sucks the liquid in the reservoir 201 into the nozzle so that the liquid can be sprayed on the DUT. The atomizers 115 are also configured to mix the fluid from the reservoir 201 with the air provided by the air source 221 to generate an atomized fluid spray that is sprayed on the DUT. It will be appreciated that although the description is described with reference to the atomizers 115, the system 200 does not necessarily need to atomize the liquid.

Water from a mechanical or electronic chiller 226 is directed through flexible water tubing to the flow sensor 227, passes over the thermistor 228 into the heat exchanger 203 over the thermistor 229 into the condenser 213 and back to the chiller 226. The thermistors 228 and 229 are electronically connected to a thermistor controller 230 which in turn is connected to the PLC 225.

The thermal electric coolers 204 are electronically connected to a thermal electric cooler controller 231 which is connected to a DC power supply 232 which is connected to an AC power source 233. The thermal electric cooler controller 231 and the DC power supply 232 are also connected electronically to the PLC 225.

The PLC 225 is also connected to the exhaust valve 210, reservoir drain valve 217, condenser drain valve 215 and tank pressure valve 219 through the valve control unit 234. The PLC 225 is also connected to the human machine interface 235, temperature relative humidity sensors 211 and 236, water chiller 226, differential pressure sensor 237, reservoir temperature thermistor 238, heat exchanger temperature thermistor 239, heat exchanger water temp in and out thermistors 228 and 229, respectively, air heater 240 and the chilled water flow sensor 227.

In one embodiment, the PLC 225 is configured to calculate the energy dissipated from the DUT in the cooling mode and display that information on the HMI 235 using the inputs from the temperature of the fluid entering and leaving the heat exchanger 203 using the in and out thermistors 228 and 229, respectively, and the chilled water flow sensor 227.

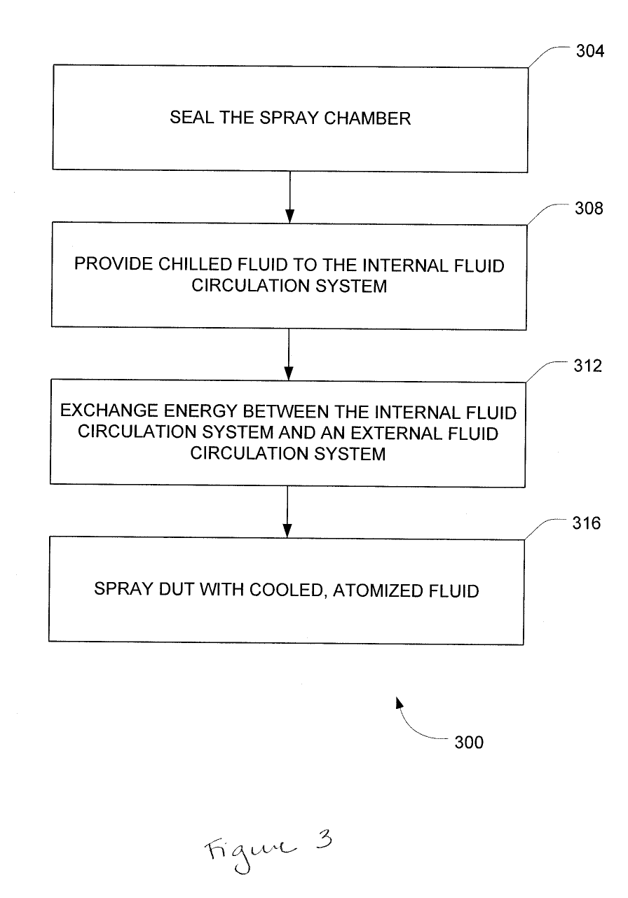

FIG. 3 illustrates a process 300 for cooling the chamber using the system 200. It will be appreciated that the process 300 described below is merely exemplary and may include a fewer or greater number of steps, and that the order of at least some of the steps may vary from that described below.

The process 300 begins by sealing the chamber (block 304). For example, with reference to FIG. 2, with exhaust valve 210 and reservoir drain valve 217 closed, a small amount of pressurized air from the electronically controlled regulator 224 enters the air driven venturi atomizers 115. While electronically monitoring the reservoir pressure sensor 223 with PLC 225, the sprayhead is raised up until the vacuum assisted rubber seal 208 seals against the DUT fixture plate 180. In this position the chamber 222 is sealed and the air pressure entering the venturi atomizers 115 causes the reservoir pressure sensor 237 to send a signal to the PLC 225 that the chamber is sealed.

The process 300 continues by providing fluid to the internal fluid circulation system of the chamber (block 308). For example, with reference again to FIG. 2, the air pressure to the venturi atomizers 115 is then turned off, the exhaust valve 210 is opened, and the reservoir drain valve 217 is opened to supply pressurized air to the water supply tank 214 through the tank pressure valve 219. The supply of pressurized air to the water supply tank 214 causes the water to back-fill into the reservoir 201. After the reservoir 201 is back-filled to a predetermined amount, the reservoir drain valve 217 is closed and the tank pressure valve 219 is turned off.

The process 300 continues by exchanging energy between the internal fluid circulation system and the external circulation system (block 312). For example, with reference to FIG. 2, with water in the reservoir 201, electrical current is conducted into the thermal electric coolers 204 such that heat from the water in the reservoir 201 is pumped into the water cooled heat exchanger 203. Heat pumped into the heat exchanger 203 from the thermal electric coolers 204 is removed by circulating chilled water from the water chiller 226. A water temperature set-point for the water chiller 226 is calculated by the PLC 225 using the temperature-relative-humidity-sensor 236 such that the temperature of the heat exchanger 203, the optical extension sleeve 205 and the microscope objective 105 remains just above the room dew point temperature. Because the temperature remains just above the room dew point temperature the structure of the microscope objective 105 is thermally stable and prevents condensation from forming on the optics and other system components.

The process 300 continues by spraying the DUT with cooled, atomized fluid (block 316). For example, with reference to FIG. 2, the heat that is pumped out of the reservoir 201 is controlled via a TEC controller 231 and the PLC 225 by monitoring the water temperature using the thermistor 238. When the water reaches a predetermined temperature, air pressure is allowed to enter the venturi atomizers 115 through the regulator 224. Air moving through the venturi atomizers 115 draws water from the reservoir 201 and creates a fine atomized mist which is directed towards the DUT fixture plate 209 to cool the DUT.

Heat from the DUT is removed by the water phase change that occurs as the small water droplets from the mist vaporize on the surface of the DUT and from direct heat conduction into the water that does not vaporize.

The water that does vaporize travels into the exhaust port 218, through the exhaust valve 210 and then into the water cooled condenser 213. Inside the condenser 213 the water vapor cools back into liquid form and is periodically released through the condenser drain valve 215 by the PLC 225 into the water supply tank 214. The water in the chamber 222 that did not vaporize after making contact with the DUT, absorbs heat from the DUT and drips back into the reservoir 201 where it is re-cooled and re-circulated back to the venturi atomizers 115. Periodically, the PLC 225 opens the reservoir drain valve 217, applies air pressure into the water supply tank 214 through the tank pressure vale 219 and replaces the water in the reservoir 201 that was lost through vaporization.

In one embodiment, the process 300 can be modified to provide additional cooling of the DUT. For example, the water in the reservoir 201 can be allowed to drop to a temperature just above the freezing point. The additional temperature drop that occurs due to the venturi effect at the venturi atomizers 115 causes the water droplets of the venturi mist to form ice crystals. For example, the inventor observed that temperature drops of about 10° C. can occur at the atomizers 115 due to the venturi effect. These ice crystals undergo a double phase change from solid to liquid to vapor upon contact with the heated DUT to provide the additional cooling.

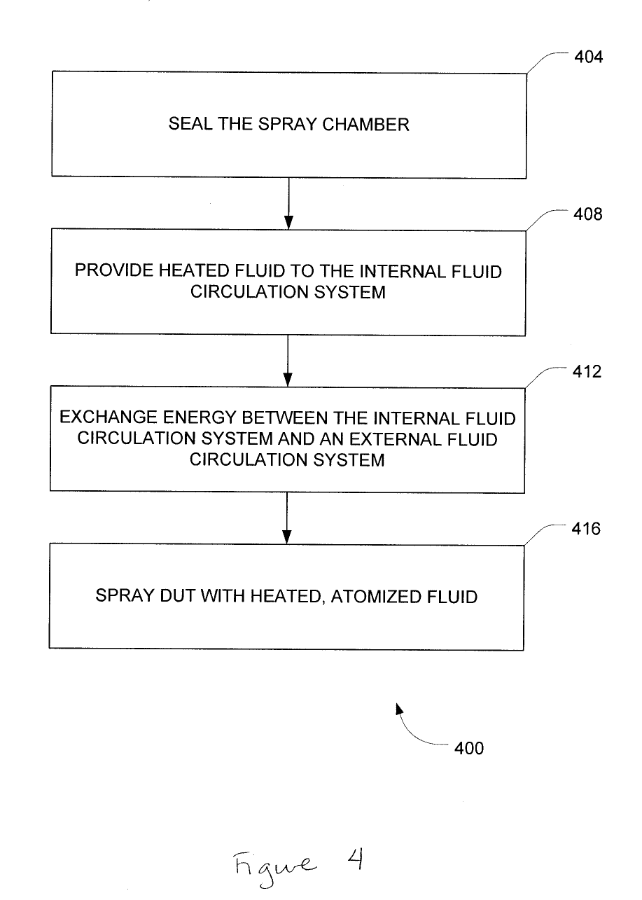

FIG. 4 illustrates a process 400 for heating the chamber using the system 200. It will be appreciated that the process 400 described below is merely exemplary and may include a fewer or greater number of steps, and that the order of at least some of the steps may vary from that described below.

The process 400 begins by sealing the chamber (block 404). With the exhaust valve 210 and reservoir drain valve 217 closed, a small amount of pressurized air from the electronically controlled regulator 224 enters the air driven venturi atomizers 115. While electronically monitoring the reservoir pressure sensor 223 with the PLC 225, the sprayhead is raised up until the vacuum assisted rubber seal 208 seals against the DUT fixture plate 180. In this position the chamber 222 is sealed and the air pressure entering the venturi atomizers 115 causes the reservoir pressure sensor 237 to send a signal to the PLC 225 that the chamber is sealed.

The process 400 continues by providing fluid to the internal fluid circulation system of the chamber (block 408). The air pressure to the venturi atomizers 115 is turned off, the exhaust valve 210 is opened, the reservoir drain valve 217 is opened and pressurized air enters the water supply tank 214 through the tank pressure valve 219 causing the water to back-fill into the reservoir 201. After the reservoir 201 is back-filled to a predetermined amount, the reservoir drain valve 217 is closed, and the tank pressure valve 219 is turned off.

The process 400 continues by exchanging energy between the internal fluid circulation system and the external circulation system (block 412). With water in the reservoir 201, electrical current is conducted into the thermal electric coolers 204 such that heat from the heat exchanger 203 as well as heat generated from the thermal electric process is pumped into the reservoir 201 and heats the water contained therein. The heat that is pumped out of the heat exchanger 203 is controlled via the TEC controller 231 and the PLC 225 by monitoring the water temperature thermistor 238.

The process 400 continues by spraying the DUT with heated, atomized water (block 416). When the water reaches a predetermined temperature, air pressure is allowed to enter the venturi atomizers 115 through the regulator 224. Air moving through the venturi atomizers 115 draws water from reservoir 201 and creates a fine atomized mist of hot water that is directed towards the DUT fixture plate 180 to heat the DUT. During the heating process, the air heater 240 that is controlled by the PLC 225 heats the air entering the venturi atomizers 115 by a predetermined amount to offset the heat that would be lost due to the venturi-effect which occurs at the venturi atomizers 115.

Water vapor from sealed chamber 222 travels into the exhaust port 218, through the exhaust valve 210, passes over temperature-relative-humidity-sensor 211 and then enters the water cooled condenser 213. The temperature set-point for the chilled water circulating through the condenser is calculated by the PLC 225 using the temperature-relative-humidity-sensors 211 and 236. The set-point is such that it is warm enough to be above the room dew point temperature but cool enough to be below the dew point temperature of the vapor exiting the chamber 222. As a result, condensation occurs in the condenser but not on the optics of microscope objective 105 or other system components.

Inside the condenser 213 the water vapor cools back into liquid form and is periodically released through the condenser drain valve 215 by the PLC 225 into the water supply tank 214. The water in the chamber 222 that did not vaporize after making contact with the DUT, transfers its heat into the DUT through conduction and drips back into the reservoir 201 where it is re-heated and re-circulated back to the venturi atomizers 115. Periodically, the PLC 225 opens the reservoir drain valve 217, applies air pressure into the water supply tank 214 through the tank pressure valve 219 and replaces the water in the reservoir 201 that was lost through vaporization.

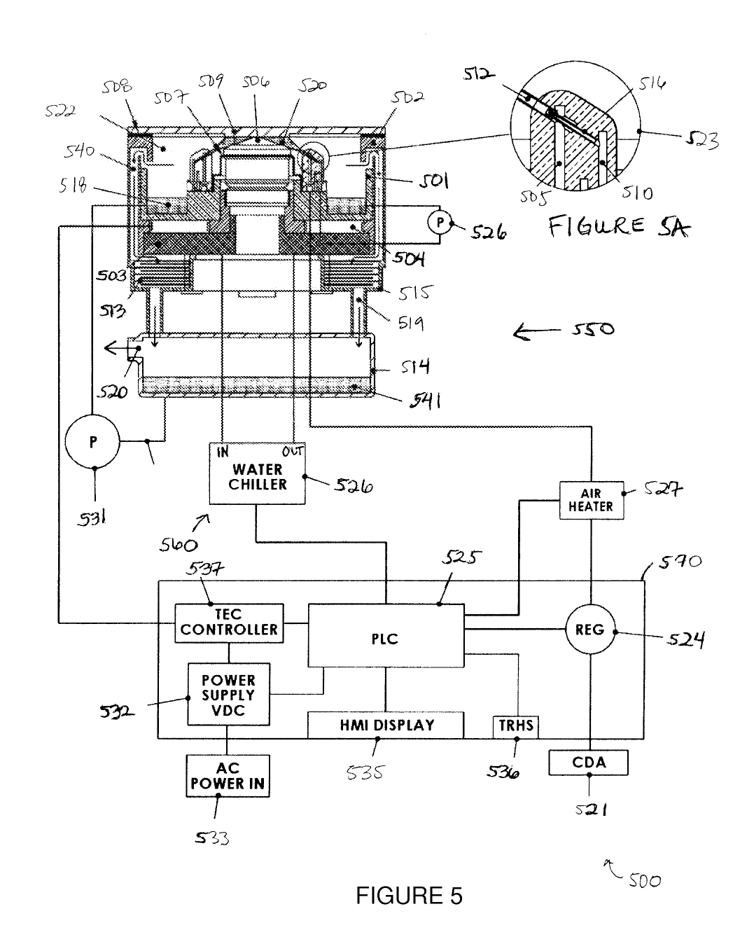

FIG. 5 illustrates another embodiment of a system 500 for heating and cooling a semiconductor device under test (DUT). The system 500 uses electronically and pneumatically cooled and heated atomized water and air (or other fluids and/or gases). It will be appreciated that the system 500 described below is merely exemplary and may include a fewer or greater number of components, and that the arrangement of at least some of the components may vary from that described below and shown in FIG. 5.

The illustrated temperature system 500 includes the spray chamber 125 that includes an internal fluid circulation system 550, an external fluid circulation system 560 and a control system 570. The internal fluid circulation system 550 off loads its energy to the external fluid circulation system 560 via a heat exchanger 503. Energy is exchanged between the internal fluid circulation system 550 and the external fluid circulation system 560 without exchanging fluid between the internal and external fluid systems.

The control system 570 includes a PLC 525 that is connected to the internal fluid communication system 550 and the external fluid circulation system 560. The control system 570 is configured to control the operation of the various components of the system 500 and monitor the temperature and pressure at various locations of the system 500. The heat exchanger 503 may be any time of heat exchanger, such as, for example, shell and tube heat exchangers, plate heat exchangers, and the like. In one embodiment, the heat exchanger 503 is thermally connected to the microscope objective 506. A protective rubber boot 507 connects to the top of microscope objective 506 and is elastically sealed to reservoir 501. A rubber seal 508 is provided to seal the chamber 522 between the insulating jacket 502 and the DUT fixture plate 509.

The external fluid circulation system includes a chiller 526 that is connected to the heat exchanger 503. The chiller provides chilled water to the heat exchanger 503 such that energy can be exchanged between the external fluid circulation system 560 and the internal fluid circulation system 550 at the heat exchanger 503. Water from the chiller 526 is directed through flexible water tubing into the heat exchanger 503 and back out to the chiller 526. The chiller 526 may be a mechanical or electronic water chiller.

The internal fluid circulation system 550 includes a reservoir 501. The illustrated reservoir 501 is made from a material of high thermal conductivity such as, for example, copper or aluminum. The reservoir 501 is encased in an insulating jacket 502. The insulating jacket 502 may be made from a material having good insulating properties such as, for example, Kynar. The reservoir 501 is connected to the heat exchanger 503 through thermo electric coolers 504 via holes cut through the bottom of insulating jacket 502.

The internal fluid circulation system 550 also includes a condenser 515 and a recirculation tank 514. Air exhaust ports 518 run through the insulating jacket 502 and connect the chamber 522 to the condenser 515. The condenser 515 includes condensing plates 513. In one embodiment, the condensing plates 513 are circular copper condensing plates. The condenser plates 513 are thermally connected to the heat exchanger 503 and are arranged in a pattern that forces an air/water vapor mixture to flow in a back and forth path over the surface of the disks. Condenser exhaust ports 519 connect the condenser 515 to the water recirculation tank 514. A recirculation pump 531 connects the water recirculation tank 514 back to the chamber 522 and reservoir 501 with flexible tubing 511. The pump 531 pumps water from the recirculation tank 514 to the reservoir 501 when the fluid level in the reservoir 501 is low.

The internal fluid circulation system 550 also includes atomizers 523 that are located within the sealed chamber 522. In one embodiment, the atomizers 523 are air driven venturi atomizers 523. The atomizers 523 are connected to an electronic regulator 524 through air ports 505. The regulator 524 is electronically controlled by the PLC 525. A clean dry air source 521 supplies air to the atomizers 523. A boost pump 526, water ports 510, and flexible water tubing are provided to connect the atomizers 523 to the reservoir 501. As shown in detail in FIG. 5A, within the atomizers 523, a water tube 516 connects to a water port 510 and runs longitudinally and concentric into the nozzle tube 512. When pressurized air passes through the nozzle tube 512, a vacuum is created that sucks the liquid in the reservoir 501 into the nozzle so that the liquid can be sprayed on the DUT. The atomizers 523 are also configured to mix the fluid from the reservoir with the air provided by the air source 521 to generate an atomized fluid spray that is sprayed on the DUT. It will be appreciated that although the description is described with reference to the atomizers 523, the system 500 does not necessarily need to atomize the liquid.

The thermal electric coolers 504 are electronically connected to a thermal electric cooler controller (TEC) 537 which is connected to a DC power supply 532 which is connected to an AC power source 533. The thermal electric cooler controller 531 and the DC power supply 532 are also connected electronically to the PLC 525. The PLC 525 is also connected to the human machine interface (HMI) 535 and a temperature relative humidity sensor 536.

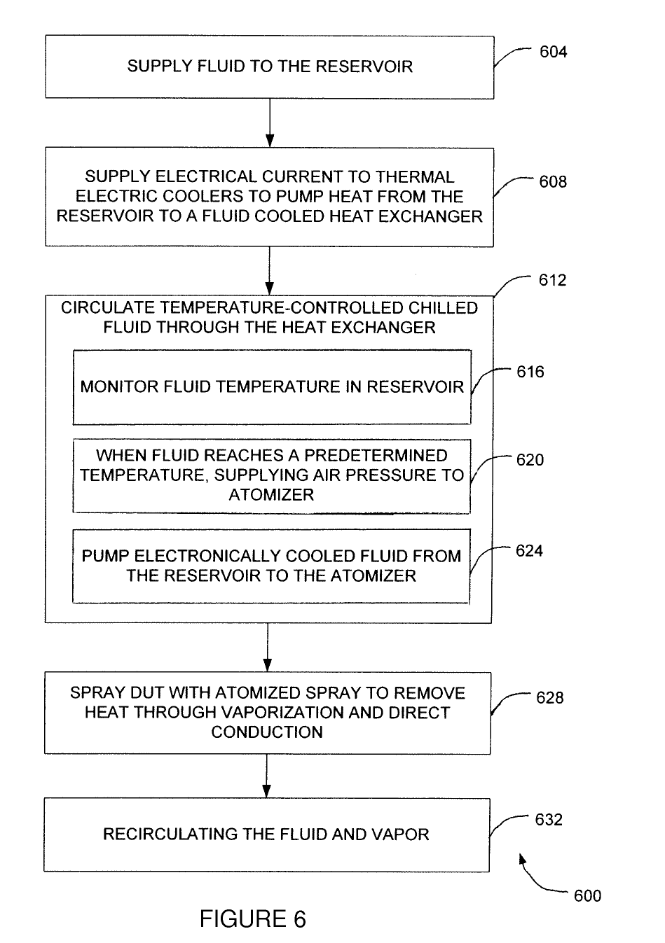

FIG. 6 illustrates a process 600 for cooling the chamber using the system 500. It will be appreciated that the process 600 described below is merely exemplary and may include a fewer or greater number of steps, and that the order of at least some of the steps may vary from that described below.

As shown in FIG. 6, the process 600 begins by supplying water to the reservoir (block 604). For example, water from the recirculation tank 514 is pumped into the reservoir 501 by the recirculation pump 531 through the flexible tubing 511.

The process 600 continues by supplying electrical current to the thermal electric coolers to pump heat from the reservoir to a water cooled heat exchanger (block 608). For example, electrical current is conducted into the thermal electric coolers 504 such that heat from the water in the reservoir 501 is pumped into the water cooled heat exchanger 503.

The process 600 continues by circulating temperature-controlled chilled water through the heat exchanger (block 612). For example, heat pumped into the heat exchanger 503 from the chamber is removed by circulating chilled water provided from the water chiller 526.

Circulating the temperature-controlled chilled water through the heat exchanger (block 612) includes monitoring the temperature in the reservoir (block 616), and when water reaches a predetermined temperature, supplying air pressure to the atomizer (block 620) and pumping electronically cooled water from the reservoir to the atomizer (block 624). For example, a water temperature set-point for the chiller 526 is calculated by the PLC 525 using the temperature-relative-humidity-sensor 536 such that the temperature of the heat exchanger 503, as well as the thermally connected microscope objective 506, remains just above the room dew point temperature. This keeps the structure of the microscope objective 506 thermally stable and prevents condensation from forming on the optics and other system components. The heat pumped out of the reservoir 501 is controlled via TEC controller 537 and PLC 525 by monitoring the water temperature inside the reservoir 501. When the water reaches a predetermined temperature, air pressure from the regulator 524 is allowed to enter the venturi atomizers 523 through the air port 505 which then forms a high velocity airstream through the nozzle tube 512. Electronically cooled water 519 from the reservoir 501 is pumped by boost pump 526 through water port 510 and injected into the high velocity airstream through the water tube 516. Shear force from the high velocity airstream atomizes the injected water stream into a fine atomized mist 520. The atomized mist 520 is then further cooled as it leaves the nozzle tube 512 due to the heat dissipation created by the expansion of the compressed air as it exits the nozzle tube.

The process 600 continues by spraying the DUT with an atomized spray to remove heat through vaporization and direct conduction (block 628). For example, the atomized mist 520 is directed towards the DUT fixture plate 509 to cool the DUT. Heat from the DUT is removed by the phase change that occurs as the tiny water droplets from the mist vaporize on the surface of the DUT and also from direct heat conduction into the water that does not vaporize.

The process 600 continues by recirculating the vapor and water (block 632). For example, the air/water vapor mixture created by the phase change at the DUT travels into the exhaust ports 540, through the insulating jacket 502 and down into the condenser 515. Because the plates 513 in the condenser 515 are thermally connected to the heat exchanger 503, which is set to the dew point temperature of the environment, the water vapor in the air/water vapor mixture condenses on the plates leaving a mixture of dry air and liquid water flowing through the condenser. Air flowing over the condenser plates 513 drives the condensed water droplets into the recirculation tank 514 where the condensed water 541 accumulates on the bottom of the tank as the dry air exits through the exhaust port 520. The level of the water 519 in the copper reservoir 501 is monitored by the PLC 525 and replenished with water 541 from the recirculation tank 514 through the pump 531 and flexible tubing 511 as needed.

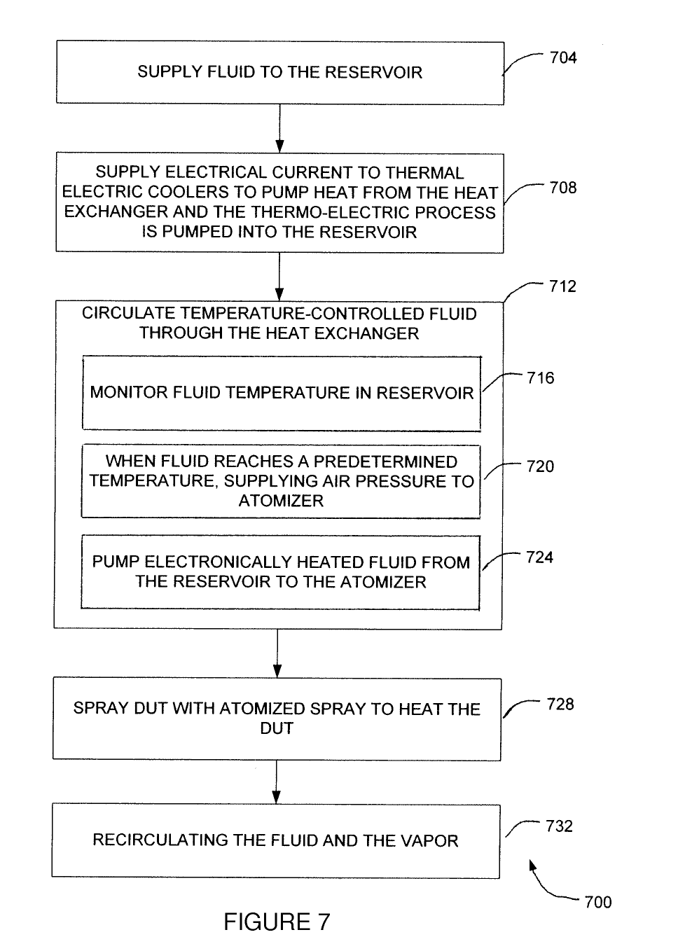

FIG. 7 illustrates a process 700 for heating the chamber using the system 500. It will be appreciated that the process 700 described below is merely exemplary and may include a fewer or greater number of steps, and that the order of at least some of the steps may vary from that described below.

The process 700 begins by supplying water to the reservoir (block 704). For example, water from the recirculation tank 514 is pumped into the copper reservoir 501 by the recirculation pump 531 through the flexible tubing 511.

The process 700 continues by supplying electrical current to the thermal electrical coolers to pump heat from the heat exchanger and the thermoelectric process is pumped into the reservoir (block 708). For example, with water in the reservoir 501, electrical current is conducted into the thermal electric coolers 504 such that heat from the heat exchanger 503 as well as heat generated from the thermo electric process is pumped into the reservoir 501 and heats the water contained therein.

The process 700 continues by circulating temperature-controlled water through the heat exchanger (block 712). Circulating temperature-controlled water through the heat exchanger (block 712) includes monitoring the water temperature in the reservoir (block 716), and when the water reaches a predetermined temperature, supplying air pressure to the atomizer (block 720) and pumping electronically heated water from the reservoir to the atomizer (block 724). For example, the heat being pumped out of the heat exchanger 503 is controlled via TEC controller 537 and PLC 525 by monitoring the water temperature inside the reservoir 501. When the water reaches a predetermined temperature, air pressure from regulator 524 is allowed to enter the venturi atomizers 523 through the air ports 505 which then forms a high velocity airstream through the nozzle tubes 512. Electronically heated water 519 from the copper reservoir 501 is pumped by boost pump 526 through water ports 510 and is injected into the high velocity airstream through water tubes 516. Shear force from the high velocity airstream atomizes the injected hot water stream into a fine atomized mist of hot water droplets 520.

The process 700 continues by spraying the DUT with atomized spray to heat the DUT (block 728). The atomized mist 520 is directed towards the DUT fixture plate 509 to heat the DUT The increased surface area of the tiny droplets contained in the atomized mist of hot water 520, facilitate the transfer of heat from the water to the DUT. To offset the heat dissipation created by the expansion of the compressed air as it exits the nozzle tube 512, air from the regulator 524 is heated by the PLC controlled air heater 527 before it enters the air ports 505 of the venturi atomizers 523.

The process 700 continues by recirculating the vapor and fluid (block 732). For example, after the heat of the tiny water droplets of the atomized mist 520 is transferred to the DUT, the droplets drip back down into the water 519 contained in the reservoir 501. The water is reheated and recirculated to the venturi atomizers 523 via the boost pump 526. Water vapor created through the atomization of the hot water stream, is carried in the form of an air/water vapor mixture into the exhaust ports 540, through the insulating jacket 502 and down into the condenser 515. Because the plates 513 in the condenser 515 are thermally connected to the heat exchanger 503, which is set to the dew point temperature of the environment, the water vapor in the air/water vapor mixture condenses on the plates leaving a mixture of dry air and liquid water flowing through the condenser 515. Air flowing over the condenser plates 513 drives the condensed water droplets into the recirculation tank 514 where the condensed water 540 accumulates on the bottom of the tank as the dry air exits through the exhaust port 520. The level of the water 518 in the copper reservoir 501 is monitored by the PLC 525 and replenished with the water 541 from the recirculation tank 514 through the pump 531 and flexible tubing 511 as needed.

To more accurately control the temperature of the atomized mist in both the cooling and heating modes, a dedicated temperature sensing venturi atomizer aimed at an RTD may be used to feed the temperature of the atomized mist back to the PLC 525. The PLC 525 can then adjust both the air stream and water stream temperatures accordingly.

It will be appreciated that for higher temperature heating (>60 C. degrees), the air pressure may be set to zero so the nozzles heat with just a water stream alone. This eliminates any heat dissipation due to the expansion of the air stream as it exits the nozzle.

It will be appreciated that for moderately low temperatures (e.g., >−30 C. and <0 C.), a mixture of water and alcohol or water and glycol may be used to avoid freezing at 0 C. Similarly, for very low temperatures (e.g., below −30 C.) the water stream may be replaced with liquid nitrogen and the air stream replaced with nitrogen gas. The phase change of the liquid nitrogen stream as it enters the nitrogen gas stream allows very large amounts of heat dissipation from the DUT. In this mode, the TEC runs in full heating mode to stop the nozzles from freezing and eliminating any external condensation. The amount of liquid nitrogen injected into the nitrogen gas stream may be metered by a pulse width modulated cryogenic valve controlled by the PLC based on feedback from the dedicated temperature sensing venturi atomizer.

Additional cooling of the DUT can be achieved by allowing the water in the reservoir to drop to a temperature just above the freezing point. The additional temperature drop that occurs due to the venturi-effect at the venturi atomizers causes the water droplets of the venturi mist to form ice crystals. These tiny ice crystals, upon contact with the heated DUT, go through a double phase change from solid ice to liquid to vapor to provide additional cooling to the DUT.

Although certain aspects of the above description have been described with reference to the fluid being water, it will be appreciated that other fluids may be used to cool and/or heat the DUT. Similarly, although certain aspects of the above description have been described with reference to supplying air to the atomizers (or other fluid injectors), it will be appreciated that gases other than air may be supplied to the fluid atomizers.

It will be appreciated that the controller (e.g., the PLC or other components of the controller) described herein includes a machine-readable medium on which is stored one or more sets of instructions (e.g., software) embodying any one or more of the methodologies or functions described herein. It will be appreciated that the software may reside, completely or at least partially, within memory and/or within a processor of the controller during execution of the software by the controller. The software may further be transmitted or received over a network via a network interface device. In the embodiments described herein, the controller may include software that, for example, sends a control signal to the regulator to supply the air to the fluid injectors and sends a control signal to the pump when the controller determines that the water temperature in the reservoir has reached the predetermined temperature, monitors the data received from the sensor(s) to determine whether the water has reached the predetermined temperature, etc.

The term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present invention. The term “machine-readable medium” shall accordingly be taken to include, but not be limited to, solid-state memories, optical and magnetic media, and carrier waves. The term “machine-readable storage medium” shall accordingly be taken to include, but not be limited to, solid-state memories and optical and magnetic media (e.g., any type of disk including floppy disks, optical disks, CD-ROMs, magnetic-optical disks, read-only memories (ROMs), random access memories (RAMs) electrically programmable read-only memories (EPROMs), electrically erasable and programmable read only memories (EEPROMs), magnetic or optical cards, or any other type of media suitable for storing electronic instructions or data, and capable of being coupled to a computer system bus).

The invention has been described through functional modules, which are defined by executable instructions recorded on computer readable media which cause a controller to perform method steps when executed. The modules have been segregated by function for the sake of clarity. However, it should be understood that the modules need not correspond to discreet blocks of code and the described functions can be carried out by the execution of various code portions stored on various media and executed at various times.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive.

The present invention has been described in relation to particular examples, which are intended in all respects to be illustrative rather than restrictive. Those skilled in the art will appreciate that many different combinations will be suitable for practicing the present invention. Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A temperature control system for an optical microscope for an integrated circuit device under test (DUT), comprising:
a chamber;
an optical receiver situated within the chamber;
fluid injectors situated within the chamber;
a first fluid circulation system coupled to and supplying fluid to the fluid injectors; and
a second fluid circulation system for exchanging energy between fluids in the first fluid circulation system and the second fluid circulation system.

2. The system of claim 1, wherein the optical receiver comprises an objective lens.

3. The system of claim 2 further comprising a solid immersion lens coupled to the objective lens.

4. The system of claim 1, wherein the first fluid circulation system is not in fluid communication with the second fluid circulation system.

5. The system of claim 1, further comprising a heat exchanger coupled between the first fluid circulation system and the second fluid circulation system to exchange energy between the fluids in the first fluid circulation system and the second fluid circulation system.

6. The system of claim 5, wherein the heat exchanger comprises a thermal electric cooler.

7. The system of claim 1, wherein the fluid injectors comprise venturi injectors.

8. The system of claim 7, wherein the venturi injectors are structured to pass gas flow therein and mix liquid with the gas flow.

9. The system of claim 8, wherein the venturi injectors are connected to a pressurized gas source and a regulator that supply the gas flow to the venturi injectors.

10. The system of claim 9 wherein the venturi injectors are further connected to a gas heater that heats the gas flow supplied to the venturi injectors.

11. The system of claim 1, wherein the first fluid circulation system comprises:
a first reservoir situated within the chamber; and
a second reservoir situated outside the chamber and coupled to the first reservoir.

12. The system of claim 11, further comprising a condenser coupled between the chamber and the second reservoir.

13. The system of claim 1, wherein the second fluid circulation system comprises a chiller.

14. The system of claim 1, further comprising a seal structured to engage a DUT adapter plate and the chamber.

15. The system of claim 14, wherein the seal comprises a vacuum assisted rubber seal.

16. The system of claim 1, further comprising a controller coupled to the first fluid communication system and second fluid communication system to control the exchange of energy between the fluids in the first fluid communication system and the second fluid communication system.

17. The system of claim 16, further comprising:
a pressure sensor and a temperature sensor to sense the pressure and temperature in the first fluid communication system and provide the pressure and temperature data to the controller, and
a pressure sensor and a temperature sensor to sense the pressure and temperature in the second fluid communication and provide the pressure and temperature data to the controller.

18. A temperature control system for an optical microscope for an integrated circuit device under test (DUT), comprising:
a chamber;
an optical receiver situated within the chamber;
fluid injectors situated within the chamber;
a fluid circulation system coupled to and supplying liquid and gas to the fluid injectors, the fluid injectors mixing the liquid and gas and spraying the mixture on the DUT; and
a controller to control the supplying of the liquid and the gas to the fluid injectors.

19. The system of claim 18 wherein the fluid injectors comprise venturi injectors.

20. The system of claim 18 further comprising a second fluid circulation system for exchanging energy between fluids in the fluid circulation system and the second fluid circulation system.

21. The system of claim 18 wherein the fluid injectors are connected to a pressurized gas source and a regulator that supply the gas to the fluid injectors.

22. The system of claim 21 wherein the fluid injectors are further connected to a gas heater that heats the gas supplied to the fluid injectors.

23. The system of claim 21 wherein the fluid communication system comprises a reservoir of liquid in the chamber, the reservoir connected to the fluid injectors to supply the liquid to the fluid injectors.

24. The system of claim 23, wherein the fluid injectors draw liquid from the reservoir of liquid when the gas is supplied to the fluid injectors.

25. The system of claim 18 further comprising a pressure sensor and a temperature sensor to sense the pressure and temperature in the first fluid communication system and provide the pressure and temperature data to the controller.

26. The system of claim 18 wherein the fluid circulation system comprises a condenser comprising a plurality of condensing plates that are thermoelectrically coupled to a heat exchanger.

27. The system of claim 18 wherein the fluid circulation system comprises:
a reservoir, the reservoir fluidly coupled to the fluid injectors;
a condenser comprising a plurality of condensing plates;
a heat exchanger thermoelectrically coupled to the plurality of condensing plates, fluid supplied to the heat exchanger by circulated chilled water from a water chiller;
thermoelectric coolers fluidly coupled to the reservoir and the heat exchanger; and
a recirculation tank fluidly coupled to the reservoir and the condenser.

28. A method for controlling the temperature of an integrated circuit device under test (DUT) in an optical microscope comprising:
positioning the DUT in a chamber of the optical microscope;
providing a first fluid circulation system for the cooling chamber;
exchanging energy between fluids of the first fluid circulation system and a second fluid circulation system; and
supplying fluid in the first fluid circulation system to a plurality of fluid injectors; and
spraying the DUT with the fluid supplied to the plurality of fluid injectors.

29. The method of claim 28 wherein exchanging energy comprises cooling the fluid of the first fluid circulation system.

30. The method of claim 28 wherein exchanging energy comprises heating the fluid of the first fluid circulation system.

31. The method of claim 28 wherein supplying fluid to the plurality of fluid injectors further comprises supplying gas and liquid to the plurality of fluid injectors and mixing the gas and liquid in the fluid injectors, and wherein spraying the DUT with the fluid using the plurality of fluid injectors comprises spraying the DUT with the mixture.

32. A temperature control system for an optical microscope for an integrated circuit device under test (DUT), comprising:
a chamber;
an optical receiver situated within the chamber;
fluid injectors situated within the chamber;
a reservoir coupled to the fluid injectors to supply fluid to the fluid injectors;
an electronic regulator coupled to an air source to supply gas to the fluid injectors via a pump; and
a controller coupled to the reservoir and the electronic regulator to monitor the temperature of the fluid in the reservoir and when the fluid reaches a predetermined temperature, sends a control signal to the electronic regulator to supply the gas to the fluid injectors and sends a control signal to the pump to supply the fluid to the fluid injectors.

33. The temperature control system of claim 32, further comprising:
a condenser comprising a plurality of condenser plates;
a heat exchanger coupled to a chiller; and
a recirculation tank fluidly coupled to the condenser and the reservoir.
